(19) United States
(12) Patent Application Publication
(10) Pub. No.: US 2009/0212688 A1
(43) Pub. Date: Aug. 27, 2009

(54) ORGANIC LIGHT-EMITTING DEVICE

(75) Inventors: Won-Jun Song, Suwon-si (KR); Yeun-Joo Sung, Suwon-si (KR); Mu-Hyun Kim, Suwon-si (KR)

Correspondence Address: STEIN MCEWEN, LLP, 1400 EYE STREET, NW, SUITE 300, WASHINGTON, DC, 20005, US

(73) Assignee: Samsung SDI Co., Ltd, Suwon-si (KR)

(21) Appl. No.: 12/211,233

(22) Filed: Sep. 16, 2008

(30) Foreign Application Priority Data
Feb. 26, 2008 (KR) 2008-17434

(51) Int. Cl. H01J 1/63

(52) U.S. Cl. 313/504

(57) ABSTRACT

An organic light-emitting device includes a first electrode; a second electrode; an emissive layer disposed between the first electrode and the second electrode; a first hole injection layer disposed between the first electrode and the emissive layer; a second hole injection layer disposed between the first electrode and the emissive layer; and an electron transport layer disposed between the emissive layer and the second electrode. The first hole injection layer includes a metal fluoride and a first hole injecting material. The second hole injection layer includes a molybdenum oxide and a second hole injecting material. The electron transport layer includes an electron transporting material and a metal oxide. The metal oxide may be one of lithium oxide (Li₂O), molybdenum oxide (MoO₃), barium oxide (BaO), and boron oxide (B₂O₃).

### CROSS-REFERENCE TO RELATED APPLICATION

This application claims the benefit of Korean Application No. 2008-17434, filed Feb. 26, 2008, in the Korean Intellectual Property Office, the disclosure of which is incorporated herein by reference.

### BACKGROUND OF THE INVENTION

1. Field of the Invention

Aspects of the present invention relate to an organic light-emitting device, and more particularly, to an organic light-emitting device with improved driving voltage characteristics, light-emitting efficiency, and life span, and reduced power consumption by using a novel hole injecting material and a novel electron transporting material.

2. Description of the Related Art

An organic light-emitting device (OLED) is a self-emitting device including two electrodes and an organic film inserted between the two electrodes. When a current is applied to the device, the OLED emits light by the recombination of electrons and holes in the organic film. Accordingly, OLEDs are advantageous in terms of providing a lightweight thin information display device having high image quality, a fast response time, and a wide viewing angle. Such characteristics have been a driving force in the dramatic growth of OLED technology. Currently, OLEDs are used not just in mobile phones, but in a wide range of applications including various information display devices.

Such a significant growth in OLED technology has made competition with other information display devices such as TFT-LCDs inevitable, not just in the academic field, but also in industry. Thus, conventional OLEDs are facing a technological challenge, requiring improvements in efficiency and life span, and reduction of power consumption thereof.

### SUMMARY OF THE INVENTION

Aspects of the present invention provide an organic light-emitting device (OLED) having easier charge injection than devices described in the prior art, thereby reducing power consumption by reduction of voltage, as well as improving the driving voltage, light-emitting efficiency, and life span characteristics.

According to an embodiment of the present invention, there is provided an organic light-emitting device including: a first electrode; a second electrode; an emissive layer disposed between the first electrode and the second electrode; a first hole injection layer disposed between the first electrode and the emissive layer; a second hole injection layer disposed between the first hole injection layer and the emissive layer; and a first electron transport layer disposed between the emissive layer and the second electrode; wherein the first hole injection layer comprises a metal fluoride and a first hole injecting material, the second hole injection layer comprises a molybdenum oxide and a second hole injecting material, the first electron transport layer comprises an electron transporting material and a metal oxide; wherein the metal oxide is one of lithium oxide (Li₂O), molybdenum oxide (MoO₃), barium oxide (BaO), and boron oxide (B₂O₃).

According to another aspect of the present invention, the organic light-emitting device may further include second electron transport layer different from the first electron transport layer including the metal compound and the first electron transporting material. The second electron transport layer includes a second electron transporting material and does not include a metal oxide.

The organic light-emitting device according to aspects of the present invention has excellent electrical properties, and uses a novel hole injecting material suitable for fluorescent and phosphorescent devices of all colors including red, green, blue, and white. Moreover, the organic light-emitting device uses a novel electron transporting material, thereby significantly improving the electron injection ability without forming an electron injection layer. As a result, not only are the current efficiency and the voltage efficiency improved compared to when using conventional electron transporting materials, the charge balance injected to the emissive layer can also be controlled which improves the driving voltage and life span characteristics. The organic light-emitting device can be structured as such to lower the two charge injection barrier, thereby reduce power consumption, and the current efficiency can be maximized by controlling the charge mobility of the novel hole injecting material and the novel electron transporting material.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIGS. 1A and 1B are cross-sectional views schematically illustrating structures of organic light-emitting devices according to embodiments of the present invention;

FIG. 2 is an energy band diagram schematically illustrating the comparison of HOMO levels and LUMO levels of each of a plurality of layers of an organic light-emitting device according to another embodiment of the present invention;

FIG. 3 is a graph illustrating the efficiencies of organic light-emitting devices according to Example 1 and Comparative Example 1, respectively; and

FIG. 4 is a graph illustrating the power consumptions of organic light-emitting devices according to Example 1 and Comparative Example 1, respectively.

### DETAILED DESCRIPTION OF THE EMBODIMENTS

Reference will now be made in detail to the present embodiments of the present invention, examples of which are illustrated in the accompanying drawings, wherein like reference numerals refer to the like elements throughout. The embodiments are described below in order to explain the present invention by referring to the figures.

Aspects of the present invention provide an organic light-emitting device (OLED) including a first electrode, a second electrode, an emissive layer disposed between the first electrode and the second electrode, a first hole injection layer disposed between the first electrode and the emissive layer, a second hole injection layer disposed between the first electrode and the emissive layer, an electron transport layer disposed between the emissive layer and the second electrode, wherein the first hole injection layer includes a metal fluoride and a first hole injecting material, the second hole injection layer includes a molybdenum oxide and a second hole injecting material, and the electron transport layer includes an electron transporting material and a metal oxide, wherein the metal oxide is one of lithium oxide (Li₂O), molybdenum oxide (MoO₃), barium oxide (BaO), and boron oxide (B₂O₃).

Herein, it is to be understood that where is stated herein that one layer is “formed on” or “disposed on” a second layer, the first layer may be formed or disposed directly on the second layer or there may be intervening layers between the first layer and the second layer. Similarly, where it is stated that one layer is disposed between two other layers, additional layers may be present between the two other layers. Further, as used herein, the term “formed on” is used with the same meaning as “located on” or “disposed on” and is not meant to be limiting regarding any particular fabrication process.

The charge balance in an emissive layer (EML) of an organic light-emitting device (OLED) is helpful in achieving high light emitting efficiency in the OLED. To this end, aspects of the present invention provide an OLED including a hole injection layer (HIL) having a double-layered structure, including a first hole injection layer (HIL1) and a second hole injection layer (HIL2). The HIL1 includes a metal fluoride and a first hole injecting material, and the HIL2 includes molybdenum oxide and a second hole injecting material. The OLED also includes an electron transport layer (ETL) including a metal oxide and an electron transporting material. The metal oxide may be lithium oxide (Li₂O), molybdenum oxide (MoO₃), barium oxide (BaO), or boron oxide (B₂O₃).

According to an embodiment of the present invention, the HIL1 includes a mixture of a metal fluoride and a first hole injecting material, wherein the metal fluoride included in the HIL1 is a novel HIL-forming material.

Conventionally, materials used for reducing a hole injection barrier are used as pure organic base materials, in which case the materials are designed to minimize the energy gap between electrodes and the organic material. However, when the HIL1 including the mixture of the metal fluoride and the first hole injecting material according to an embodiment of the present invention is used on the electrode interface, a dipole moment is created on the electrode interface, which enables the injection of holes more organically when an electric field is applied to the OLED (induced dipole).

The metal of the metal fluoride may preferably be a Group 1 or Group 2 element. Specifically, the metal fluoride may be LiF, NaF, MgF₂, BaF, or CsF.

As a non-limiting example, the mixing ratio between the metal fluoride and the first hole injecting material may be 1:1 to 3:1. If the mixing ratio is less than 1:1, the reduction of the driving voltage is not significant, and if the mixing ratio is greater than 3:1, the driving voltage may be increased.

Moreover, the HIL2 of the OLED according to the current embodiment of the present invention includes a mixture of a molybdenum oxide and a second hole injecting material. The mixing ratio between the molybdenum oxide and the second hole injecting material may be 1:1 to 3:1. If the mixing ratio is less than 1:1, the reduction of driving voltage is not significant, and if the mixing ratio is greater than 3:1, the driving voltage may be increased.

When the mixture of the molybdenum oxide and the second hole injecting material is used in the HIL2 according to an embodiment of the present invention, the charge transport density can be increased using the electroconductivity of molybdenum oxide, and the required intensity of the electrical field for overall charge transport can be reduced by lowering the resistance within the OLED. Moreover, the energy trap distribution present in the organic structure can be reduced, and the surface morphology can be improved, thereby reducing the contact resistance on the surface and preventing charge accumulation.

The metal fluoride and the molybdenum oxide may be prepared using various methods well known to those of ordinary skill in the art.

As described previously, the first hole injecting material and the second hole injecting material may each independently be HIL-forming materials, and may be compounds conventionally used in the art. For example, the first hole injecting material and the second hole injecting material may be each independently copper phthalocyanine, 1,3,5-tricarbazolylbenzene, 4,4′-biscarbazolylbiphenyl, polyvinylcarbazole, m-biscarbazolylphenyl, 4,4′-biscarbazolyl-2,2′-dimethylbiphenyl, 4,4′,4″-tri(N-carbazolyl)triphenylamine (TCTA), 4,4′,4″-tris(3-methylphenylamino)triphenylamine (m-MTDATA), 1,3,5-tri(2-carbazolylphenyl)benzene, 1,3,5-tris(2-carbazolyl-5-methoxyphenyl)benzene, bis(4-carbazolylphenyl)silane, N,N′-bis(3-methylphenyl)-N,N′-diphenyl-[1,1′-biphenyl]-4,4′-diamine (TPD), N,N′-di(naphthalene-1-yl)-N,N′diphenyl benzidine (α-NPD), N,N′-diphenyl-N,N′-bis(1-naphthyl)-(1,1′-biphenyl)-(1,1′-biphenyl)-4,4′-diamine (NPB), poly(9,9-dioctylfluorene-co-N-(4-butylphenyl)diphenylamine (TFB) or poly(9,9-dioctylfluorene-co-bis-N,N-phenyl-1,4-phenylendiamine) (PFB).

The OLED including the HIL1 and the HIL2 according to the current embodiment of the present invention provides advantages of improved driving voltage, emission efficiency, and life span characteristics, and particularly, minimization of life span degradation during digital driving (constant voltage driving).

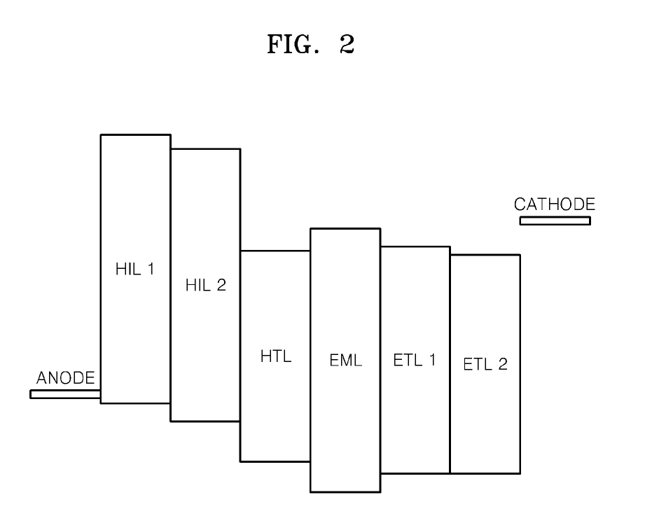

FIG. 2 is an energy band diagram schematically illustrating the comparison of HOMO (highest occupied molecular orbital) levels and LUMO (lowest unoccupied molecular orbital) levels of each of a plurality of layers of an OLED according to another embodiment of the present invention.

The OLED having such structure according to the current embodiment of the present invention can lower the charge injection barrier, and reduce the interface contact resistance, and thus life span can be significantly increased during driving.

As non-limiting examples, the thickness ratio between the HIL1 and the HIL2 may be 1:99 to 1:9. If the thickness ratio between the HIL1 and the HIL2 is lower than 1:99 that the thickness of the HIL1 is too thin compared to that of the HIL2, the properties of the HIL1 are not fully realized, and if the thickness ratio between the HIL1 and the HIL2 is greater than 1:9, the increasing rate of resistance within the OLED becomes high, and thus the driving voltage may be increased.

The metal fluoride and the molybdenum oxide may be prepared using various methods well known to those of ordinary skill in the art.

The organic light-emitting device according to the current embodiment of the present invention provides more efficient electron injection characteristics without requiring a separate electron injection layer (EIL).

The ETL1 of the OLED according to the current embodiment of the present invention includes a first electron transporting material, and the ETL2 includes a second electron transporting material and a metal oxide selected from one of lithium oxide (Li₂O), molybdenum oxide (MoO₃), barium oxide (BaO), and boron oxide (B₂O₃). In the double-layered ETL structure described above, a more organic injection of electrons can be made possible compared to when only a single ETL is used, and thus power consumption is greatly reduced due to a reduction in the voltage.

The second electron transport material includes an electron transporting material with an electron mobility of 10⁻⁸ cm/VS or greater or more specifically, 10⁻⁴ to 10⁻⁸ cm/VS) in an electric field of 800-100 (V/cm)^{1/2}.

The electron mobility of the first electron transporting material, as in the second electron transporting material, may be 10⁻⁸ cm/VS or greater, and the composition of the first electron transporting material may be the same as or different from that of the second electron transporting material. For example, with regards to the manufacturing process, the first electron transporting material and the second electron transporting material may be formed of the same materials.

The thickness ratio between the ETL1 and the ETL2 may be 1:1 to 1:2.

The first and second electron transporting materials may be Alq3 or Bebq2, and the metal oxide may be Li₂O.

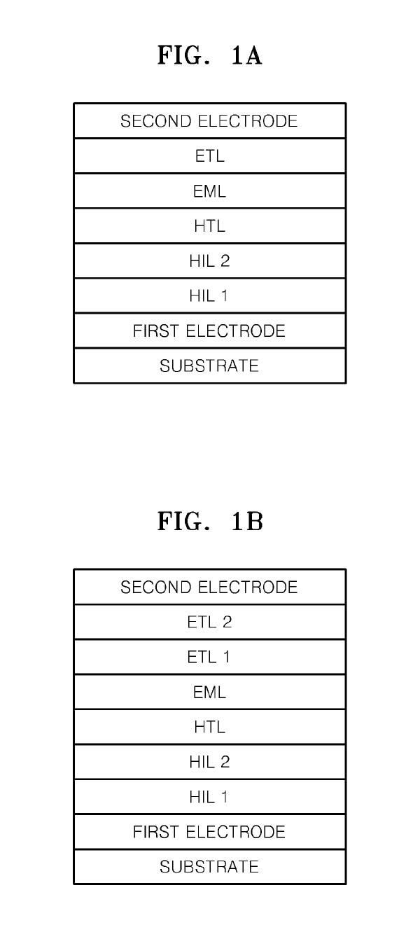

For the organic light-emitting device having a double-layered ETL structure (see FIG. 1B) the ETL1 functions to control the charge transport rate, and the ETL2 functions to lower the electron injection barrier.

The ETL2 includes the second electron transporting material and a metal oxide having a dipolar characteristic. As a specific, non-limiting example, the second electron transporting material may be Alq3, and the metal fluoride of the first hole injecting layer may be LiF, BaF, CsF, or NaF.

As a specific, non-limiting example, the first electron transporting material forming the ETL1 may be Bebq2.

The OLED according to the current embodiment of the present invention may not require an electron injection layer.

It is to be understood that the OLED according to aspects of the present invention may have a variety of structures other than the structure of anode, HIL, HTL, EML, ETL, and cathode as shown in FIGS. 1A to 1B, and that a single or double-layered intermediate layer may further be formed when necessary.

Hereinafter, a method of manufacturing the OLED according to aspects of the present invention will be described.

First, a first electrode is formed by depositing a first electrode material having a high work function on a substrate through deposition or sputtering. The first electrode may be an anode. The substrate used may be a substrate conventionally used in OLEDs. For example, the substrate may be a glass substrate or a transparent plastic substrate having excellent mechanical strength, thermal stability, transparency, surface planarity, ease of handling, and water resistance. The first electrode material may be indium tin oxide (ITO), indium zinc oxide (IZO), tin oxide (SnO₂), or zinc oxide (ZnO), which are transparent and highly conductive.

Next, an HIL1 may be formed on the first electrode, using a method such as vacuum deposition, spin coating, casting, or Langmuir-Blodgett (LB) deposition. In order to form the HIL1, a metal fluoride and an HIL-forming organic compound may be co-deposited.

An HIL2 is then formed on the HIL1 using a method such as vacuum deposition, spin coating, casting, or LB deposition. In order to form the HIL2, molybdenum oxide and an HIL-forming organic compound may be co-deposited on the HIL1.

When forming the HIL1 and the HIL2 by vacuum deposition, the deposition conditions may vary depending on the compounds used as materials for the HIL1 and the HIL2, the structure of the HIL1 and the HIL2 to be formed, and the thermal properties thereof, but generally may be appropriately selected from a deposition temperature range of 50 to 500° C., a degree of vacuum of 10⁻⁸ to 10⁻³ torr, a deposition rate of 0.01 to 100 Å/sec, and a film thickness of 10 Å to 5 μm.

The HTL may also be formed using a well-known method such as vacuum deposition, spin coating, casting, or LB deposition. When the HTL is formed using vacuum deposition or spin coating, the deposition conditions and the coating conditions may vary depending on the compounds used to form the HTL, but may be generally selected from the range of conditions used to form the HIL.

The HTL material may be appropriately selected from materials used for conventional HTLs. Examples of an HTL material include carbazole derivatives such as N-phenylcarbazole, polyvinylcarbazole, or conventional amine derivatives having an aromatic condensed ring such as N,N′-bis(3-methylphenyl)-N,N′-diphenyl-[1,1-biphenyl]-4,4′-diamine (TPD), and N,N′-di(naphthalene-1-yl)-N,N′-diphenyl benzidine (α-NPD).

Next, an EML is formed on the HTL. The EML may be formed using a well-known method such as vacuum deposition, spin coating, casting, or LB deposition.

The material forming the EML is not particularly limited. More particularly, examples of an EML material for emitting blue light include oxadiazole dimer dyes (Bis-DAOPXP), spiro compounds (Spiro-DPVBi, Spiro-6P), triarylamine compounds, bis(styryl)amine (DPVBi, DSA), 4,4′-bis(9-ethyl-3-carbazovinylene)-1,1′-biphenyl (BCzVBi), perylene, 2,5,8,11-tetra-tert-butylperylene (TPBe), 9H-carbazole-3,3′-(1,4-phenylene-di-2,1-ethene-diyl)bis[9-ethyl-(9C)] (BczVB), 4,4′-bis[4-(di-p-tolylamino)-4′-[(di-p-tolylamino)styryl]stilbene (DPAVB), 4,4′-bis[4-(diphenylamino)styryl]biphenyl (BDAVBi), and bis(3,5-difluoro-2-(2-pyridyl)phenyl-(2-carboxypyridyl) iridium (III) (FlrPic); examples of an EML material for emitting green light include 3-(2-benzothiazolyl)-7-(dimethylamino) coumarin (Coumarin 6) 2,3,6,7-tetrahydro-1,1,7,7,-tetramethyl-1H,5H, 11H-10-(2-benzothiazolyl)quinolizino-[9,9a, 1 gh] coumarin (C545T), N,N′-dimethyl-quinacridone (DMQA), tris(2-phenylpyridine) iridium(III), and (Ir(ppy)₃); and examples of an EML material for emitting red light include tetraphenylnaphthacene (Rubrene), tris(1-phenylisoquinoline) iridium (III) (Ir(piq)₃), bis(2-benzo[b]thiophene-2-yl-pyridine) (acetylacetonate) iridium (III) (Ir(btp)2(acac)), tris(dibenzoylmethane)phenanthroline europium (III) (Eu(dbm)3(phen)), tris[4,4′-di-tert-butyl-(2,2′)-bipyridine] ruthenium (III) complex (Ru(dtb-bpy)3*2(PF6)), DCM1, DCM2, Eu (thenoyltrifluoroacetone)3 (Eu(TTA)₃, and butyl-6-(1,1,7,7-tetramethyl julolidyl-9-enyl)-4H-pyran (DCJTB). Moreover, polymeric light-emitting materials include aromatic compounds including nitrogen and polymers such as phenylene-based, phenylene vinylene-based, thiophene-based, fluorene-based and spiro-fluorene-based polymers, but are not limited thereto.

The thickness of the EML may be 10 nm to 500 nm, or more specifically, 50 nm to 120 nm. In particular, the thickness of a blue region of the EML may be 70 nm. If the thickness of the EML is less than 10 nm, the leakage current may increase, thereby reducing the efficiency and life span of the OLED, and if the thickness of the EML is greater than 500 nm, the increasing rate of the driving voltage may become too high.

If desired, the EML may be prepared by adding a light-emitting dopant to an EML host. Examples of a fluorescent EML host include tris(8-hydroxy-quinolinato) aluminum (Alq3), 9,10-di(naphthyl-2-yl) anthracene (ADN), 3-tert-butyl-9,10-di(naphthyl-2-yl) anthracene (TBADN), 4,4′-bis(2,2-diphenyl-ethene-1-yl)-4,4′-dimethylphenyl (DPVBi), 4,4′-bis(2,2-diphenyl-ethene-1-yl)-4,4′-dimethylphenyl (p-DMDPVBi), tert(9,9′-diarylfluorene)s (TDAF), 2-(9,9′-spirobifluorene-2-yl)-9,9′-spirobifluorene (TSDF), bis(9,9′-diarylfluorene)s (BDAF), and 4,4′-bis(2,2-diphenyl-ethene-1-yl)-4,4′-di-(tert-butyl)phenyl (p-TDPVBi). Examples of a phosphorescent EML host include 1,3-bis(carbazol-9-yl)benzene (mCP), 1,3,5-tris(carbazol-9-yl)benzene (tCP), 4,4′,4″-tris(carbazol-9-yl) triphenylamine (TcTa), 4,4′-bis(carbazol-9-yl) biphenyl (CBP), 4,4′-bis(9-carbazolyl)-2,2′-dimethyl-biphenyl (CBDP), 4,4′-bis(carbazol-9-yl)-9,9-dimethylfluorene (DMFL-CBP), 4,4-bis(carbazol-9-yl)-9,9-bis(9-phenyl-9H-carbazol) fluorene (FL-4CBP), 4,4′-bis(carbazol-9-yl)-9,9′-di-tolyl-fluorene (DPFL-CBP), and 9,9-bis(9-phenyl-9H-carbazole) fluorene (FL-2CBP).

The amount of the dopant varies depending on the EML-forming material used, but generally, the amount may be 1 to 10 parts by weight based on 100 parts by weight of the EML-forming material (total weight of the host and dopant). If the amount of the dopant is outside the range above, light-emitting properties of the OLED may deteriorate. For example, a fluorescent EML dopant may be DPAVBi, and a fluorescent EML host may be ADN or TBADN (both shown below).

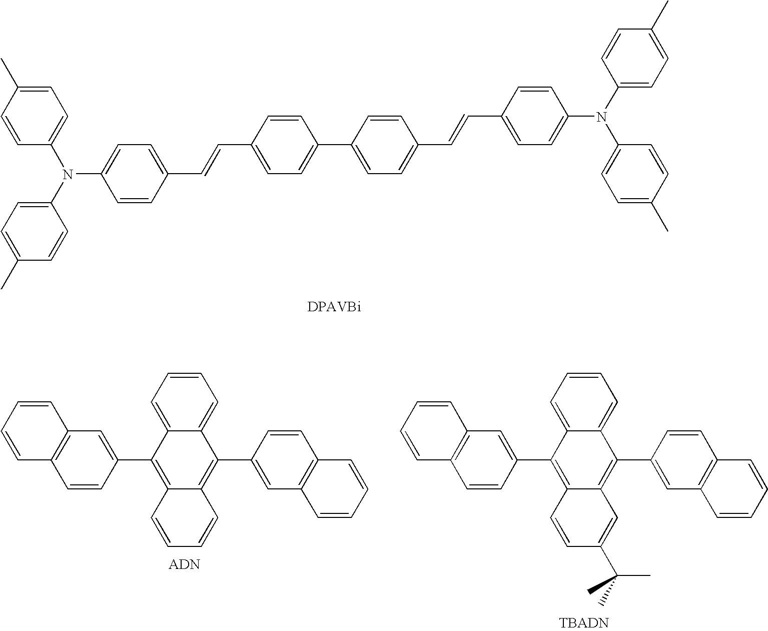

Next, the ETL is formed by depositing the electron transporting material and the previously-described metal oxide on the EML, using a vacuum deposition method.

As a non-limiting example, the content of the metal oxide may be 30 to 60 parts by weight based on 100 parts by weight of the electron transporting material. If the metal oxide content is less than 30 parts by weight based on 100 parts by weight of the electron transporting material, the ETL may not perform its function, and if the metal oxide content is greater than 60 parts by weight based on 100 parts by weight of the electron transporting material, the insulating properties of the ETL may increase, thereby increasing the driving voltage.

As a non-limiting example, the electron transporting material may be a material having an electron mobility of 10⁻⁸ cm/VS or greater, and more particularly 10⁻³ to 10⁻⁵ cm/VS in an electric field of 800-100 (V/cm)^{1/2}.

If the electron mobility of the ETL is less than 10⁻⁸ cm/VS, the electron injection in the EML may be insufficient, which is not desirable in terms of charge balance.

As a non-limiting example, the electron transporting material may be bis(10-hydroxybenzo[h]quinolinato beryllium (Bebq2), or derivatives thereof.

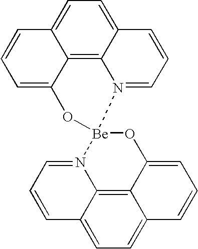

An EIL may be optionally formed on the ETL. Materials including LiF, NaCl, CsF, Li₂O, and BaO may be used to form the EIL. The deposition conditions of depositing the ETL and the EIL may vary depending on the compounds used, but may be generally selected from the range of conditions used to form the HIL.

Finally, as a second electrode, a cathode is formed on the EIL or the ETL by depositing a cathode-forming metal using a method such as vacuum deposition or sputtering. The cathode-forming metal may be a metal, an alloy, an electroconductive compound having a low work function or mixtures thereof. Specific examples of such materials include Li, Mg, Al, Al—Li, Ca, Mg—In, and Mg—Ag. In addition, a transparent cathode may be formed of ITO or IZO in order to obtain a top-emission device.

A method of preparing an OLED according to another embodiment of the present invention is described as below.

The OLED including a double-layered ETL as shown in FIG. 1B is prepared using the same method as previously described, except that the ETL1 is formed by depositing a first electron transporting material on the EML using vacuum deposition, and the ETL2 is formed by depositing a second electron transporting material and a metal oxide on the ETL1 by vacuum deposition.

Hereinafter, aspects of the present invention will be described in more detail with reference to the examples described below. However, these examples are for illustrative purposes only and are not intended to limit the scope of the invention.

### Example 1

### Preparation of OLED

An anode was prepared by cutting a Corning 15 Ωcm² (1200 Å) ITO glass substrate into a size of 50 mm×50 mm×0.7 mm, and sonicating for 5 minutes using isopropyl alcohol and deionized water, then irradiating UV light for 30 minutes and exposing the substrate to ozone to clean the substrate.

NPB and MgF₂ were co-deposited on the anode to form an HIL1 having a thickness of 50 Å. Next, NPB and MoOₓ were co-deposited on the HIL1 to form an HIL2 having a thickness of 600 Å.

NPB was vacuum-deposited on the HIL2 to form an HTL having a thickness of 40 nm. After forming the HTL, 100 parts by weight of Alq3 as a host, and 3 parts by weight of Coumarin (C545T) as a dopant were vacuum-deposited on the HTL to form an EML.

Then, 50 parts by weight of Li₂O and 50 parts by weight of Alq3 were vacuum co-deposited on the EML to form an ETL having a thickness of 35 nm.

Then, an Al cathode was formed by vacuum-depositing 3000 Å of Al on the ETL, thereby completing the manufacture of an OLED.

### Example 2

### Preparation of OLED

An OLED was manufactured using the same method as in Example 1, except that the ETL was formed by vacuum co-depositing 50 parts by weight of lithium quinolate and 50 parts by weight of Alq3.

### Comparative Example 1

### Preparation of OLED

An OLED was manufactured using the same method as in Example 1, except that a co-deposition structure including HIL1, HIL2, and ETL was used.

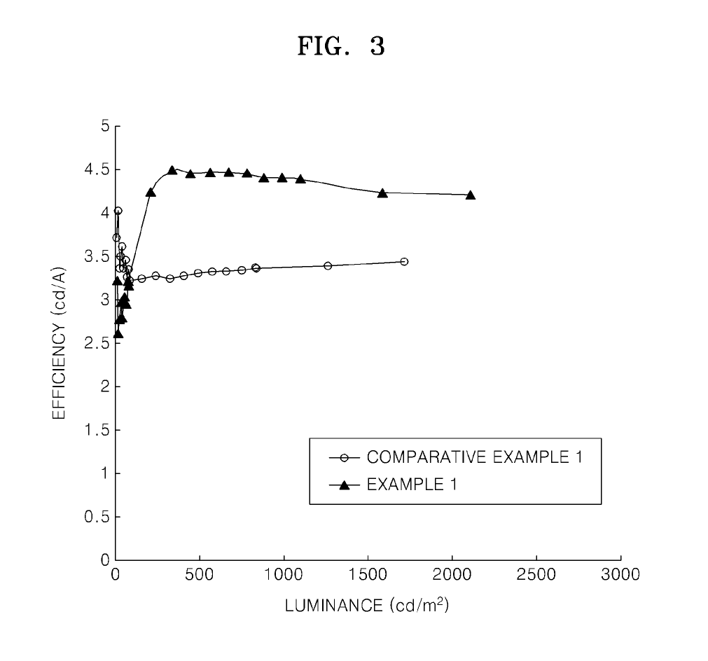

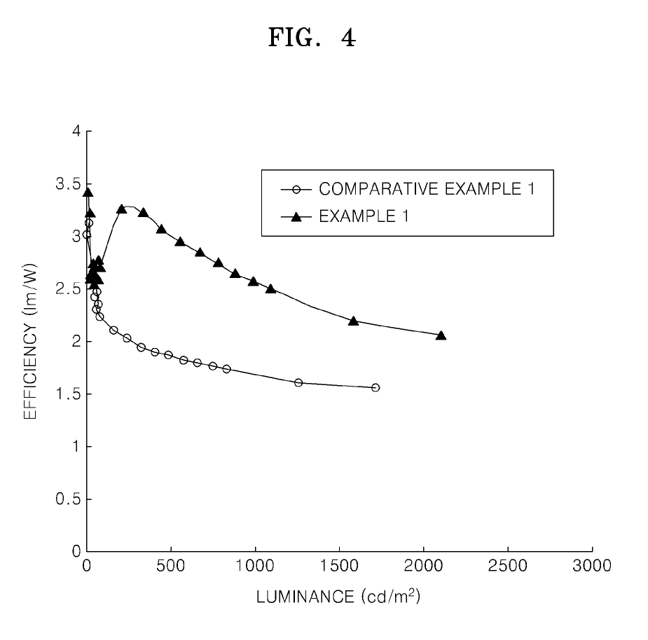

FIG. 3 is a graph illustrating the power efficiencies of the OLEDs manufactured according to Example 1 and Comparative Example 1, respectively. As shown in FIG. 3, the OLED according to Example 1 showed a greater power efficiency. FIG. 4 is a graph illustrating the power consumptions of the OLEDs manufactured according to Example 1 and Comparative Example 1, respectively. Here again, the OLED according to Example 1 showed greater efficiency.

The organic light-emitting device according to aspects of the present invention has excellent electrical properties, and uses a novel hole injecting material suitable for fluorescent and phosphorescent devices of all colors including red, green, blue, and white. Moreover, the organic light-emitting device uses a novel electron transporting material, thereby significantly improving the electron injection ability without requiring an electron injection layer. As a result, not only the current efficiency and the voltage efficiency are improved compared to when using conventional electron transporting materials, the charge balance of charges injected to the EML can also be controlled which improves the driving voltage and life span characteristics. The organic light-emitting device can be structured as such to lower the injection barriers of two charges, thereby reducing power consumption, and the current efficiency can be maximized by controlling the charge mobility of the novel hole injecting material and the novel electron transporting material. The device also has high brightness and a long life span.

Although a few embodiments of the present invention have been shown and described, it would be appreciated by those skilled in the art that changes may be made in this embodiment without departing from the principles and spirit of the invention, the scope of which is defined in the claims and their equivalents.

What is claimed is:

1. An organic light-emitting device (OLED) comprising:
a first electrode;
a second electrode;
an emissive layer disposed between the first electrode and the second electrode;
a first hole injection layer disposed between the first electrode and the emissive layer;
a second hole injection layer disposed between the first hole injection layer and the emissive layer; and
an electron transport layer disposed between the emissive layer and the second electrode,
wherein
the first hole injection layer comprises a metal fluoride and a first hole injecting material,
the second hole injection layer comprises a molybdenum oxide and a second hole injecting material, and
the electron transport layer comprises an electron transporting material and a metal oxide, wherein the metal oxide is one of lithium oxide (Li₂O), molybdenum oxide (MoO₃), barium oxide (BaO), and boron oxide (B₂O₃).

2. The organic light-emitting device of claim 1, wherein the mixing ratio between the metal fluoride and the first hole injecting material in the first hole injection layer is 1:1 to 3:1.

3. The organic light-emitting device of claim 1, wherein the first hole injection layer is formed by co-depositing the metal fluoride and the first hole injecting layer.

4. The organic light-emitting device of claim 1, wherein the mixing ratio between the molybdenum oxide and the second hole injecting material in the second hole injecting layer is 1:1 to 3:1.

5. The organic light-emitting device of claim 1, wherein the second hole injection layer is formed by co-depositing the molybdenum oxide and the second hole injecting layer.

6. The organic light-emitting device of claim 1, wherein the metal in the metal fluoride is a Group 1 or a Group 2 element.

7. The organic light-emitting device of claim 1, wherein the metal fluoride is LiF, NaF, MgF₂, BaF, or CsF.

8. The organic light-emitting device of claim 1, wherein the first hole injecting material and the second hole injecting material are each independently selected from the group consisting of copper phthalocyanine, 1,3,5-tricarbazolylbenzene, 4,4′-biscarbazolylbiphenyl, polyvinylcarbazole, m-biscarbazolylphenyl, 4,4′-biscarbazolyl-2,2′-dimethylbiphenyl, 4,4′,4″-tri(N-carbazolyl)triphenylamine (TCTA), 4,4′,4″-tris(3-methylphenylamino)triphenylamine (m-MTDATA), 1,3,5-tri(2-carbazolylphenyl)benzene, 1,3,5-tris(2-carbazolyl-5-methoxyphenyl)benzene, bis(4-carbazolylphenyl)silane, N,N′-bis(3-methylphenyl)-N,N′-diphenyl-[1,1′-biphenyl]-4,4′-diamine (TPD), N,N′-di(naphthalene-1-yl)-N,N′-diphenyl benzidine (α-NPD), N,N′-diphenyl-N,N′-bis(1-naphthyl)-(1,1′-biphenyl)-(1,1′-biphenyl)-4,4′-diamine (NPB), poly(9,9-dioctylfluorene-co-N-(4-butylphenyl)diphenylamine (TFB) and poly(9,9-dioctylfluorene-co-bis-N,N-phenyl-1,4-phenylendiamine) (PFB).

9. The organic light-emitting device of claim 1, wherein the thickness ratio between the first hole injection layer and the second hole injection layer is 1:99 to 1:9.

10. The organic light-emitting device of claim 1, wherein the amount of the metal oxide is 30 to 60 parts by weight based on 100 parts by weight of the electron transporting material.

11. The organic light-emitting device of claim 1, wherein the electron mobility of the electron transporting material is 10⁻⁸ cm/VS or greater in an electric field of 800-100 (V/cm)^{1/2}.

12. The organic light-emitting device of claim 1, wherein the electron transporting material comprises at least one selected from the group consisting of tris(8-hydroxy-quinolinato) aluminum (Alq3), bis(10-hydroxybenzo[h]quinolinato beryllium) (Bebq2) represented by the structure below, and derivatives thereof:

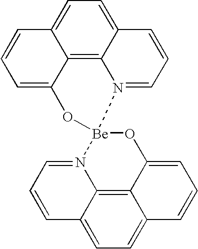

13. The organic light-emitting device of claim 1, wherein the organic light emitting device does not have a separate electron injection layer.

14. An organic light-emitting device (OLED) comprising:
a first electrode;
a second electrode;
an emissive layer disposed between the first electrode and the second electrode;
a first hole injection layer disposed between the first electrode and the emissive layer;
a second hole injection layer disposed between the first hole injection layer and the emissive layer;
an first electron transport layer disposed between the emissive layer and the second electrode, and
a second electron transport layer disposed between the first electron transport layer and the second electrode
wherein
the first hole injection layer comprises a metal fluoride and a first hole injecting material,
the second hole injection layer comprises a molybdenum oxide and a second hole injecting material,
the first electron transport layer comprises a first electron transporting material and does not include a metal oxide, and
the electron transport layer comprises a second electron transporting material and a metal oxide, wherein the metal oxide is one of lithium oxide (Li₂O), molybdenum oxide (MoO₃), barium oxide (BaO), and boron oxide (B₂O₃).

15. The organic light-emitting device of claim 14, wherein the first electron transport layer lowers an electron transport rate to the emitting layer, and the second electron transport layer lowers an electron injection barrier with respect to the second electrode.

16. The organic light-emitting device of claim 14, wherein the second electron transporting material has an electron mobility of 10⁻³ cm/VS or greater in an electric field of 800-100 (V/cm)^{1/2}.

17. The organic light-emitting device of claim 14, wherein the second electron transporting material has an electron mobility of 10⁻³ to 10⁻⁵ cm/VS in an electric field of 800-100 (V/cm)^{1/2}.

18. The organic light-emitting device of claim 14, wherein the thickness ratio between the first electron transport layer and the second electron transport layer is 1:1 to 1:2.

19. The organic light-emitting device of claim 1, further comprising at least one layer selected from the group consisting of an additional hole injection layer, a hole transport layer, an electron blocking layer, an emissive layer, a hole blocking layer, an additional electron transport layer, and an electron injection layer.

20. The organic light-emitting device of claim 1, having one of the following structures:
first electrode/first hole injection layer/second hole injection layer/hole transport layer/emissive layer/electron transport layer/second electrode,
first electrode/first hole injection layer/second hole injection layer/hole transport layer/emissive layer/electron transport layer/electron injection layer/second electrode, and
first electrode/first hole injection layer/second hole injection layer/hole transport layer/emissive layer/hole blocking layer/electron transport layer/electron injection layer/second electrode.
